(19) United States
(12) Patent Application Publication
(10) Pub. No.: US 2023/0307563 A1
(43) Pub. Date: Sep. 28, 2023

(54) Woven Photo-voltaic Structure

(71) Applicant: Paul Benedict Huter, Denver, CO (US)

(72) Inventor: Paul Benedict Huter, Denver, CO (US)

(21) Appl. No.: 16/676,440

(22) Filed: Nov. 7, 2019

(51) Int. Cl. H01L 31/0352; H01L 31/054

(52) U.S. Cl. CPC H01L 31/035281; H01L 31/0547

(57) ABSTRACT

Photo-voltaic, or solar, arrays have been developed and advanced for decades, and the quality of the technology has led to advances in conversion of photons to electrons. However, there is a limitation to the number of photons which may be collected, and this disadvantage is to be addressed by this patent application.

No cross-reference

No federally-sponsored research or development

No join research agreement

No sequence listing

No prior disclosures

### BACKGROUND

The idea for this invention is based on a planar photo-voltaic cell not being capable of absorbing all photons. Therefore, by applying a three-dimensional structure to a photo-voltaic application, additional photons will be captured, resulting in improved power generation from the photo-voltaic structure.

### SUMMARY

This invention is for a photo-voltaic structure that is three-dimensional. The structure is manufactured by weaving individual “strands” of photo-voltaic material into a three-dimensional structure.

### DRAWINGS

The included drawing(s) show a representative woven photo-voltaic structure.

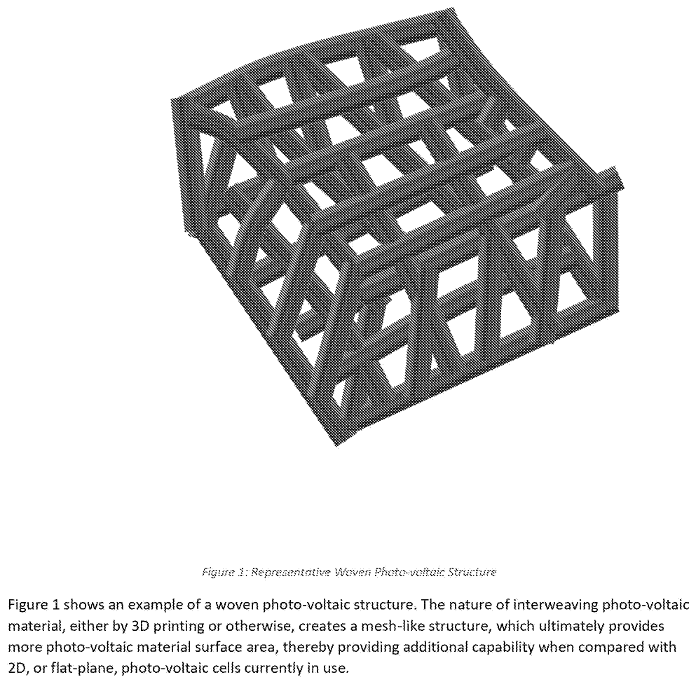

a. FIG. 1 shows an example of a woven photo-voltaic structure. The nature of interweaving photo-voltaic material, either by 3D printing or otherwise, creates a mesh-like structure, which ultimately provides more photo-voltaic material surface area, thereby providing additional capability when compared with 2D, or flat-plane, photo-voltaic cells currently in use.

### DETAILED DESCRIPTION

The proposed photo-voltaic structure includes a woven three-dimensional structure that allows for additional photon-energy to be captured and transmitted as power, thereby improving the efficiency over the current two-dimensional photo-voltaic structures.

Photo-voltaic cells are in widespread use around the world. However, current cell technology presents a two-dimensional face to the sun to generate an electric current. While the sun provides a steady stream of photons to the surface of current solar arrays, there are abundant photons that are being reflected from surfaces behind and around current solar arrays, which are not hitting the surface of the cell, and, thus, not generating an electric current.

1) By forming a three-dimensional solar structure, it is possible to collect photons from all angles, and by weaving silicon “wires” together, it will be possible to collect photons which pass by other layers of silicon or are reflected off of the surface. FIG. 1 shows a representative example of a woven photo-voltaic structure in a cube form. Other forms with more layers or other shapes are possible, so long as the woven silicon wires do not short the electric current or interfere with the passage of photons between multiple layers.
